(19) United States
(12) Patent Application Publication
(10) Pub. No.: US 2014/0001625 A1
(43) Pub. Date: Jan. 2, 2014

(54) SEMICONDUCTOR DEVICES AND METHODS OF MANUFACTURING THE SAME

(71) Applicant: SAMSUNG ELECTRONICS CO., LTD., Suwon-si (KR)

(72) Inventors: HAUK HAN, Hwaseong-si (KR); Ho-Ki LEE, Seongnam-si (KR); HyunSeok LIM, Seo-gu (KR); Kihyun YUN, Seoul (KR); MYOUNGBUM LEE, Seoul (KR); Jeonggil LEE, Hwaseong-si (KR); Tai-Soo LIM, Seoul (KR)

(21) Appl. No.: 13/933,398

(22) Filed: Jul. 2, 2013

(30) Foreign Application Priority Data
Jul. 2, 2012 (KR) 10-2012-0071721

(51) Int. Cl. H01L 23/49

(52) U.S. Cl. CPC H01L 23/49
USPC 257/698

(57) ABSTRACT

A semiconductor device may include a contact mold layer on a substrate, the contact mold layer defining first and second contact portions on the substrate, a wire mold layer on the contact mold layer, and first and second wires penetrating the wire mold layer and extending in a first direction, the first and second wires contacting the respective first and second contact portions and the contact mold layer. The first and second wires may be arranged in an alternating manner, and the first and second contact portions may be arranged to have a zigzag configuration. Each of the first and second contact portions may include a conductive pattern and a barrier pattern, and the barrier pattern may have a top surface lower than a top surface of the contact mold layer.

### CROSS-REFERENCE TO RELATED APPLICATION

This U.S. non-provisional patent application claims priority under 35 U.S.C. §119 to Korean Patent Application No. 10-2012-0071721, filed on Jul. 2, 2012, in the Korean Intellectual Property Office, and entitled: “SEMICONDUCTOR DEVICES AND METHODS OF FABRICATING THE SAME,” the entire contents of which are hereby incorporated by reference.

### BACKGROUND

1. Field

Embodiments relate to semiconductor devices and methods of fabricating semiconductor devices.

2. Description of the Related Art

Due to their small-size, multifunctionality, and/or low-cost characteristics, semiconductor devices are widely used in the electronic industry. Semiconductor devices may be classified into, e.g., a memory device for storing data, a logic device for processing data, and a hybrid device including both memory and logic elements.

Due to the increased demand for electronic devices with a fast speed and/or a low power consumption, the semiconductor device may be expected to exhibit a fast operating speed and/or a low operating voltage. To satisfy these technical requirements, the semiconductor device may be expected to have a high integration density, that is, more elements per area.

### SUMMARY

Embodiments are directed to a semiconductor device. The semiconductor device may include a contact mold layer on a substrate, the contact mold layer defining first and second contact portions on the substrate, a wire mold layer on the contact mold layer, first wires penetrating the wire mold layer and extending in a first direction, the first wires contacting the first contact portions and the contact mold layer, and second wires penetrating the wire mold layer and extending in the first direction, the second wires contacting the second contact portions and the contact mold layer. The first and second wires may be arranged in an alternating manner, the first and second contact portions may be arranged to have a zigzag configuration, each of the first and second contact portions may include a conductive pattern and a barrier pattern that covers side and bottom surfaces of the conductive pattern, and the barrier pattern of each of the first and second contact portions may have a top surface lower than a top surface of the contact mold layer.

A top surface of the conductive pattern of each of the first and second contact portions and the top surface of the contact mold layer may be substantially coplanar with each other, and the wire mold layer may fill a gap between the conductive pattern of each of the first and second contact portions and the contact mold layer.

The first and second wires may have bottom surfaces that are lower than a top surface of the conductive pattern of each of the first and second contact portions and are higher than the top surface of the barrier pattern of each of the first and second contact portions.

A top surface of the conductive pattern of each of the first and second contact portions may be lower than the top surface of the contact mold layer and may be substantially coplanar with the top surface of the barrier pattern of each of the first and second contact portions.

Each of the first and second wires may include a plug portion connected to a corresponding one of the first and second contact portions and a line portion spaced apart from the first and second contact portions, and a bottom surface of the line portion of each of the first and second wires may have a different vertical level than a bottom surface of the plug portion of each of the first and second wires.

Each of the first and second wires may include a plug portion connected to a corresponding one of the first and second contact portions and a line portion spaced apart from the first and second contact portions, and the plug portion of each of the first and second wires may have a bottom width that is smaller than a bottom width of the line portion of each of the first and second wires.

Embodiments are also directed to a method of manufacturing a semiconductor device. The method may include forming a contact mold layer on a substrate, forming contact holes to penetrate the contact mold layer, forming contact portions in the contact holes, respectively, each of the contact portions including a barrier layer and a conductive layer sequentially provided in a corresponding one of the contact holes, partially etching top surfaces of the contact portions to form recess regions, forming a wire mold layer to cover the contact mold layer, patterning the wire mold layer to form grooves that extend along a first direction and expose the contact portions, and forming wires to fill the grooves.

Forming the recess regions may include partially etching top surfaces of the barrier and conductive layer of each of the contact portions, such that the barrier and conductive layer of each of the contact portions have top surfaces lower than a top surface of the contact mold layer.

The wire mold layer may be formed to fill the recess regions and to have voids in the recess regions.

The grooves may include first grooves and second grooves formed in an alternating manner, and a bottom surface of each of the first and second grooves on the contact portions may have a different vertical level than a bottom surface of each of the first and second grooves on the contact mold layer.

The first and second grooves may be simultaneously formed using a same etching process, and forming the first and second grooves may include removing the voids to expose the contact portions.

The contact portions may be formed to have a zigzag arrangement.

Forming the recess regions may include partially and selectively etching a top surface of the barrier layer of each of the contact portions, such that the top surface of the barrier layer of each of the contact portions is lower than a top surface of the contact mold layer.

The wire mold layer may be formed to fill a gap between the contact mold layer and the conductive layer of each of the contact portions.

The wires may have bottom surfaces that are lower than a top surface of the conductive layer of each of the contact portions and are higher than the top surface of the barrier layer of each of the contact portions.

Embodiments are also directed to a semiconductor device that includes a contact mold layer on a substrate, the contact mold layer defining first contact portions and second contact portions on the substrate, the first and second contact portions having a zigzag configuration, and a wire mold layer on the contact mold layer, the wire mold layer defining first wires and second wires that extend substantially parallel to each other along a top surface of the contact mold layer, each of the first wires including a portion that extends below the top surface of the contact mold layer to contact one of the first contact portions, and each of the second wires including a portion that extends below the top surface of the contact mold layer to contact one of the second contact portions.

The portion of each of the first wires that extends below the top surface of the contact mold layer may have a bottom width that is smaller than a bottom width of a portion of each of the first wires that extends along the top surface of the contact mold layer, and the portion of each of the second wires that extends below the top surface of the contact mold layer may have a bottom width that is smaller than a bottom width of a portion of each of the second wires that extends along the top surface of the contact mold layer.

The first and second contact portions may each include a conductive pattern and a barrier pattern that covers side and bottom surfaces of the conductive pattern, and the conductive pattern and the barrier pattern of each of the first and second contact portions may have top surfaces that are substantially coplanar with each other and are below the top surface of the contact mold layer.

The first and second contact portions may each include a conductive pattern and a barrier pattern that covers side and bottom surfaces of the conductive pattern, the conductive pattern of each of the first and second contact portions may have a top surface that is substantially coplanar with the top surface of the contact mold layer, and the barrier pattern of each of the first and second contact portions may have a top surface that is below the top surface of the contact mold layer.

The first and second contact portions may each include a conductive pattern and a barrier pattern that covers side and bottom surfaces of the conductive pattern, the barrier pattern of each of the first and second contact portions may have a top surface that is below the top surface of the contact mold layer, and a portion of the wire mold layer may extend below the top surface of the contact mold layer and may be above the top surface of the barrier pattern of each of the first and second contact portions.

### BRIEF DESCRIPTION OF THE DRAWINGS

Features will become apparent to those of skill in the art by describing in detail exemplary embodiments with reference to the attached drawings in which:

FIG. 1 is a plan view illustrating an interconnection structure according to example embodiments.

FIGS. 2 through 7 illustrate sectional views taken along a line of I- I′ of FIG. 1 to illustrate stages of a method of fabricating an interconnection structure, according to example embodiments.

FIGS. 8 through 12 illustrate sectional views taken along a line of I-I′ of FIG. 1 to illustrate stages of a method of fabricating an interconnection structure, according to other example embodiments.

FIG. 13A is a plan view illustrating a semiconductor device according to example embodiments.

FIG. 13B illustrates a sectional view taken along line II-II′ of FIG. 13A.

FIG. 13C illustrates a sectional view taken along line of FIG. 13A.

FIG. 14A is a plan view illustrating a semiconductor device according to other example embodiments.

FIG. 14B illustrates a sectional view taken along line IV-IV′ of FIG. 14A.

FIG. 14C illustrates a sectional view taken along line V-V′ of FIG. 14A.

FIG. 15A is a plan view illustrating a semiconductor device according to still other example embodiments.

FIG. 15B illustrates a sectional view taken along line VI-VI′ of FIG. 15A.

FIG. 15C illustrates a sectional view taken along line VII-VII′ of FIG. 15A.

FIG. 16 is a schematic block diagram illustrating an example of an electronic system including a semiconductor device according to example embodiments.

FIG. 17 is a schematic block diagram illustrating an example of a memory card including a semiconductor device according to example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will also be understood that when a layer is referred to as being “between” two layers, it can be the only layer between the two layers, or one or more intervening layers may also be present. It will be understood that when an element is referred to as being “connected,” it can be directly connected to the other element or intervening elements may be present. In contrast, when an element is referred to as being “directly connected” to another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items. Like reference numerals refer to like elements throughout.

It should be noted that the drawings are not to scale and may not precisely reflect the precise structural or performance characteristics of any given embodiment, and should not be interpreted as defining or limiting the range of values or properties encompassed by example embodiments. For example, the relative thicknesses and positioning of layers, regions, and/or structural elements may be reduced or exaggerated for clarity.

It will be understood that, although the terms “first,” “second,” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

As used herein, the singular forms “a,” “an,” and “the” are intended to include the plural forms as well, unless the context clearly indicates otherwise. It will be further understood that the terms “comprises,” “comprising,” “includes” and/or “including,” specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

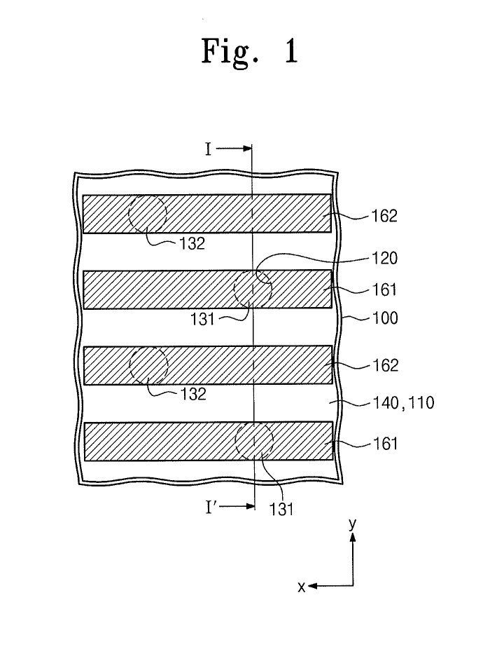

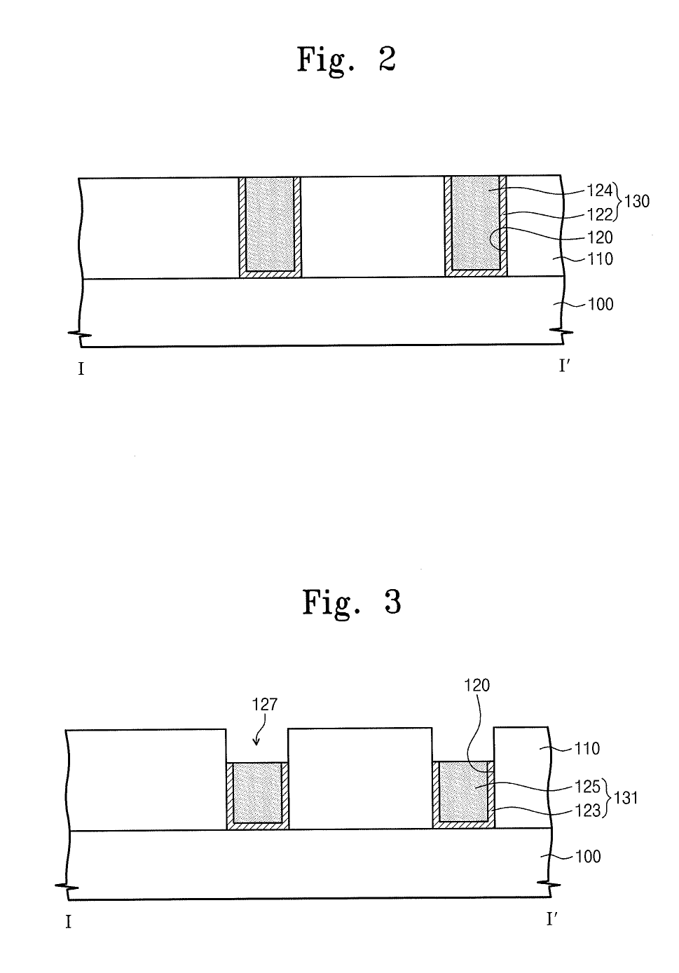

FIG. 1 is a plan view illustrating an interconnection structure according to example embodiments. FIGS. 2 through 7 are sectional views taken along a line of I-I′ of FIG. 1 to illustrate stages in a method of fabricating an interconnection structure, according to example embodiments.

Referring to FIG. 1, mold layers 110 and 140 may be provided on a substrate 100, and wires 161 and 162 may be provided on the mold layer 110 and 140 to extend parallel to a first direction. The substrate 100 may be a semiconductor substrate (e.g., of silicon, germanium, or silicon-germanium). At least one of the mold layers 110 and 140 may be provided in the form of a single- or multi-layered structure. At least one of the mold layers 110 and 140 may include a layer of oxide, nitride and/or oxynitride. The wires 161 and 162 may extend parallel to each other along the first direction and may be arranged spaced apart from each other in a second direction crossing the first direction. The first and second directions may be parallel to a top surface of the substrate 100. For example, the first direction may be an x-direction of FIG. 1, and the second direction may be a y-direction of FIG. 1.

Contact portions 131 and 132 may be connected to bottom surfaces of the wires 161 and 162, respectively. In example embodiments, the contact portions 131 and 132 may be downward extended portions of the wires 161 and 162, respectively. For example, each of the contact portions 131 and 132 may form a single body along with the corresponding one of the wires 161 and 162. In other words, each of the contact portions 131 and 132 may be in direct contact with the corresponding one of the wires 161 and 162, without any discontinuous interface therebetween. Each of the contact portions 131 and 132 may be in contact with the substrate 100 through at least one of the mold layers 110 and 140.

In example embodiments, as illustrated in FIG. 1, the contact portions 132 connected to even-numbered ones (e.g., 162) of the wires may be arranged along the second direction to form a first column, and the contact portions 131 connected to odd-numbered ones (e.g., 161) of the wires may be arranged along the second direction to form a second column provided at one side of the first column. As illustrated in FIG. 1, the contact portions 131 and 132 may be arranged in a zigzag manner along the second direction. Although not illustrated, a plurality of conductive pillars may be provided between the substrate 100 and the contact portions 131 and 132 in such a way that they are arranged laterally spaced apart from each other. The wires 161 and 162 and the contact portions 131 and 132 may be variously modified in terms of width and shape.

The contact portions 131 and 132 and the wires 161 and 162 may include at least one conductive material. For example, the contact portions 131 and 132 and the wires 161 and 162 may include the same conductive material. In example embodiments, the contact portions 131 and 132 and the wires 161 and 162 may include a metal layer (e.g., of tungsten, aluminum, or copper). Further, the contact portions 131 and 132 and the wires 161 and 162 may further include a barrier metal (e.g., of titanium nitride or tantalum nitride) to suppress metallic elements from being diffused. In addition, the contact portions 131 and 132 and the wires 161 and 162 may further include a glue layer (e.g., of titanium or tantalum).

The afore-described semiconductor device may be used to realize, e.g., a logic device, a semiconductor memory device, or a hybrid device including both of logic and memory elements. Hereinafter, a method of fabricating an interconnection structure, according to example embodiments will be described in greater detail with reference to sectional views taken along a line I-I′ of FIG. 1.

Referring to FIGS. 1 and 2, a contact mold layer 110 may be formed on the substrate 100. For example, the contact mold layer 110 may include an oxide or nitride layer. Contact holes 120 may be formed on the substrate 100 to penetrate the contact mold layer 110. Although not illustrated, the formation of the contact holes 120 may include forming a mask pattern on the contact mold layer 110 and etching the contact mold layer 110 using the mask pattern as an etch mask. The contact holes 120 may penetrate the contact mold layer 110 and expose the substrate 100.

Contact portions 130 may be formed in the contact holes 120. Each of the contact portions 130 may include a barrier layer 122 and a conductive layer 124. The barrier layer 122 may be formed to conformally cover side and bottom surfaces of each of the contact holes 120, and the conductive layer 124 may be formed to fill the contact holes 120 provided with (conformally covered with) the barrier layer 122. The barrier layer 122 may include a conductive material capable of preventing metallic elements from being diffused. For example, the barrier layer 122 may include a titanium nitride layer or a tantalum nitride layer. The conductive layer 124 may include a metal material (e.g., of tungsten, aluminum, or copper). Thereafter, a polishing process may be performed to expose a top surface of the contact mold layer 110, and thus the contact portions 130 may be formed spaced apart from each other, as illustrated in FIG. 2.

Referring to FIGS. 1 and 3, the contact portions provided in the contact holes 120 may be partially etched to form first recess regions 127, such that top surfaces of the contact portions are lower than that of the contact mold layer 110. The formation of the first recess regions 127 may include partially etching top surfaces of the barrier layer 122 and the conductive layer 124 provided within each of the contact holes 120. In example embodiments, the first recess regions 127 may be formed by etching the barrier layer 122 and the conductive layer 124 using an etch recipe having etch selectivity with respect to the contact mold layer 110. The etching process may include a dry and/or wet etching process.

As the resulting of the process of partially etching the barrier layer 122 and the conductive layer 124, a barrier pattern 123 and a conductive pattern 125 may be formed in each of the contact holes 120. Top surfaces of the barrier pattern 123 and the conductive pattern 125 may be lower than that of the contact mold layer 110 and higher than that of the substrate 100. The barrier pattern 123 and the conductive pattern 125 may constitute the first contact portion 131, whose top surface is lower than that of the contact mold layer 110. In example embodiments, the second contact portions 132 may be formed using the process for forming the first contact portions 131, and thus, the second contact portions 132 may have the same technical features as those of the first contact portions 131.

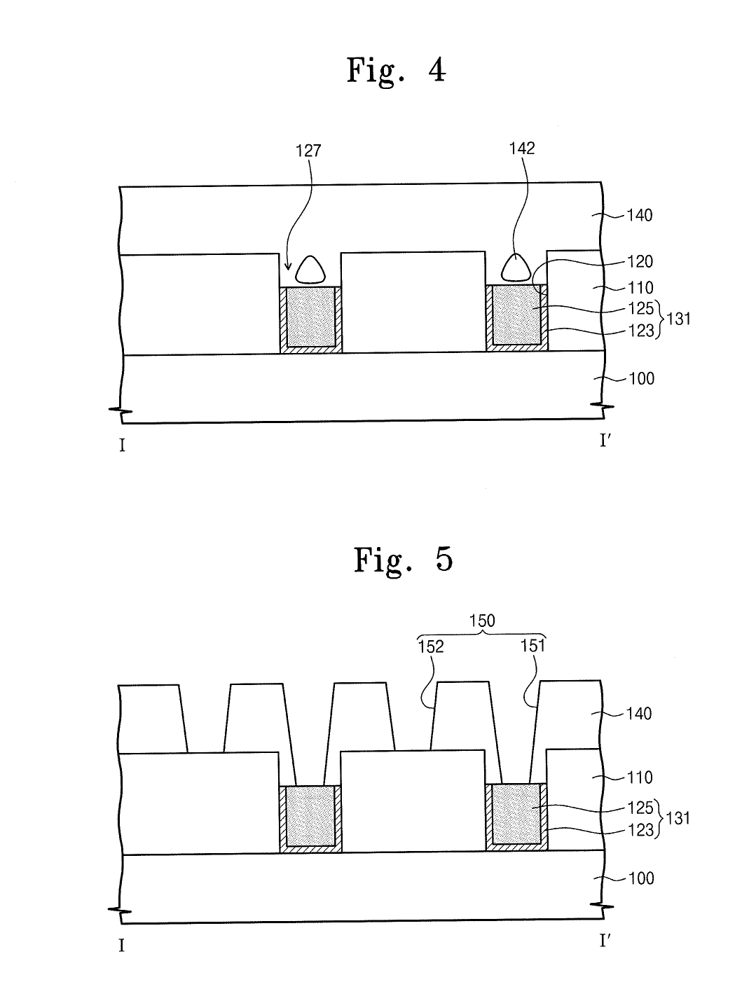

Referring to FIGS. 1 and 4, the wire mold layer 140 may be formed on the substrate 100. The wire mold layer 140 may be formed to cover the contact mold layer 110 and the contact portions 131 and 132. In other words, the wire mold layer 140 may be formed to cover the top surface of the contact mold layer 110 and top surfaces of the first and second contact portions 131 and 132.

During the formation of the wire mold layer 140, voids 142 may be formed in the first recess regions 127. In other words, the first recess regions 127 may not be completely filled with the wire mold layer 140, thereby forming the voids 142. In example embodiments, the wire mold layer 140 may include an oxide layer (e.g., of TEOS). The formation of the wire mold layer 140 may be performed to intentionally form the voids 142 in the first recess regions 127. For example, the wire mold layer 140 may be formed of a material exhibiting a gap-fill property suitable for forming the voids 142.

Referring to FIGS. 1 and 5, grooves 150 may be formed through the wire mold layer 140. The grooves 150 may have a shape elongated along the first direction (e.g., a direction crossing the line I-P). The grooves 150 may include first grooves 151 and second grooves 152 exposing top surfaces of the contact portions 131 and 132, respectively. In example embodiments, the first and second grooves 151 and 152 may be formed to expose the top surface of the contact mold layer 110. Accordingly, in a vertical section view taken along the second direction, the grooves 150 may include the first and second grooves 151 and 152, whose bottom surfaces are different from each other. The second grooves 152 may be formed between the first grooves 151 spaced apart from each other. In other words, as illustrated in FIG. 5, the first and second grooves 151 and 152 may be alternatingly arranged to each other.

In example embodiments, the first and second grooves 151 and 152 may be simultaneously formed, for example, using the same process. For example, the formation of the first and second grooves 151 and 152 may include an etching process to expose the top surface of the contact mold layer 110. During the etching process, the first and second grooves 151 and 152 may be formed to expose the voids 142, which may be formed within the first recess regions 127. Here, the first and second grooves 151 and 152 may be over-etched due to the presence of the voids 142 to expose the top surfaces of the contact portions 131 and 132.

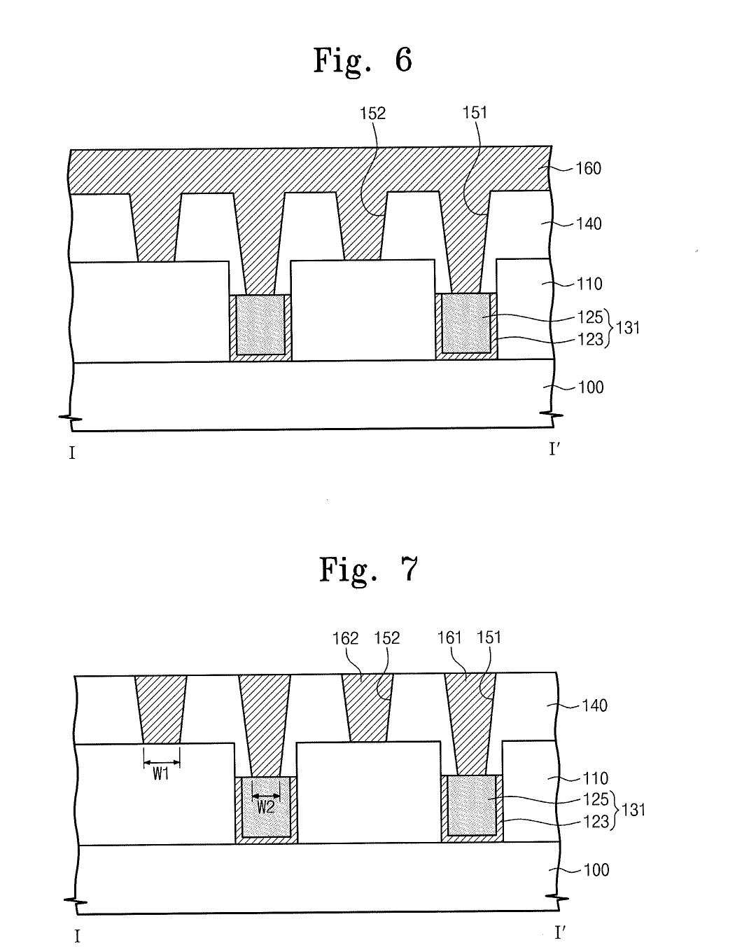

Referring to FIGS. 1 and 6, a wire conductive layer 160 may be formed on the substrate 100 to fill the first and second grooves 151 and 152. Accordingly, the contact portions 131 and 132 may be electrically connected to each other via the wire conductive layer 160. The wire conductive layer 160 may include a metal material (e.g., tungsten, aluminum, or copper). In example embodiments, the wire conductive layer 160 may be formed of the same material as the conductive pattern 125, such that the wire conductive layer 160 may be in contact with the conductive pattern 125 without any interface therebetween.

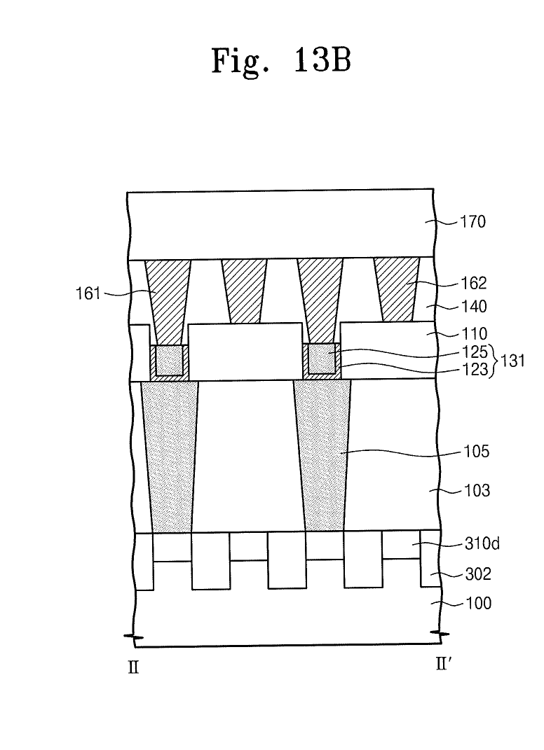

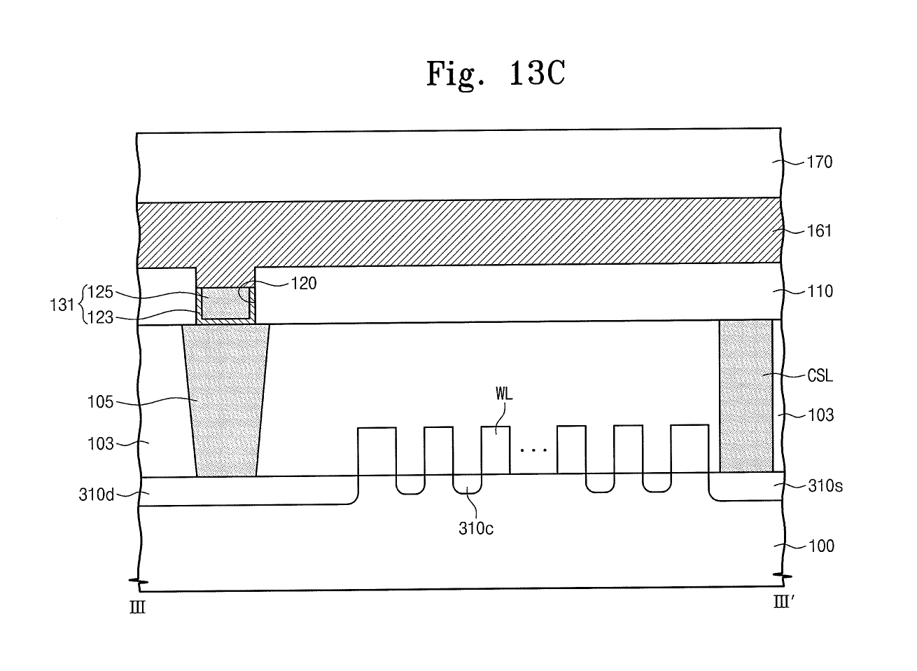

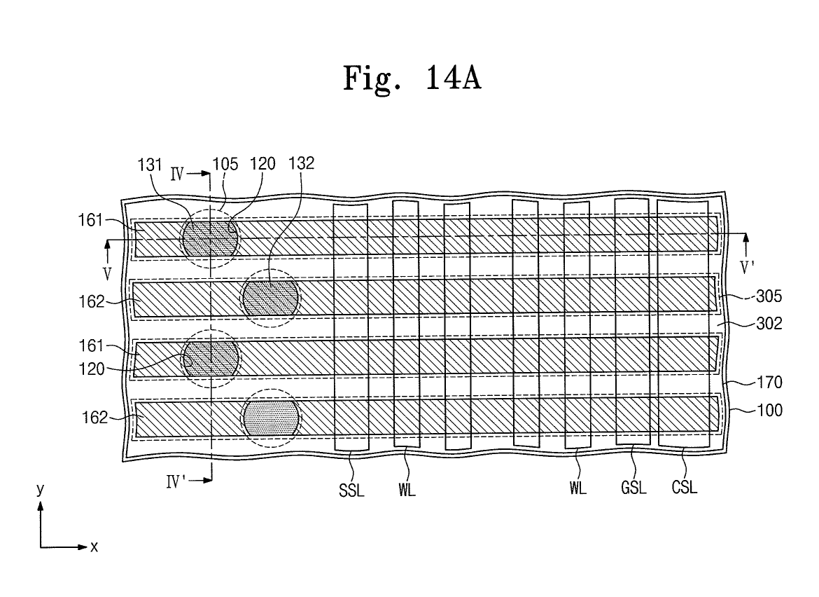

Referring to FIGS. 1 and 7, a polishing process may be performed to expose the top surface of the wire mold layer 140, thereby forming the wires 161 and 162. The wires may include first wires 161 provided in the first grooves 151, respectively, and second wires 162 provided in the second grooves 152, respectively. In a vertical section view taken along the second direction, the first and second wires 161 and 162 may be formed to have bottom surfaces with vertical levels that are different from each other. For example, each of the first and second wires 161 and 162 may include a plug portion in contact with the corresponding one of the contact portions 131 and 132 and at least one line portion in contact with the top surface of the contact mold layer 110. The plug portion may be positioned on the contact holes 120, while the line portion may be positioned out of the contact holes 120. For example, as illustrated in FIGS. 13C, 14C, and 15C (which are discussed in greater detail below), the plug portion of the first wire 161 may extend into the contact hole 120 and may have a bottom surface lower than a bottom surface of the line portion of first wire 161, which line portion may be the portion of the first wire 161 that does not extend into the contact hole 120. Although only the first wire 161 is illustrated in FIGS. 13C, 14C, and 15C, the second wire 162 may have the same arrangement except that the locations of the plug portion and the line portion may be adjusted to correspond to the different location of the contact hole 120 (e.g., based on the zigzag configuration of the contact portions 131 and 132).

The first and second wires 161 and 162 may be disposed spaced apart from each and arranged in an alternating manner. The alternating arrangement of the first and second wires 161 and 162 may enable a space between bottom portions of the first and second wires 161 and 162 to be increased. By contrast, in the case where a bottom surface of the line portion is positioned at the same level as that of the plug portion, the semiconductor device may suffer from a reduced breakdown voltage, which may be caused by a reduced space between the wires or the wire and the contact portion. According to example embodiments, it is possible to substantially prevent the reduction in breakdown voltage of the semiconductor device, because the line portions of the first wires 161 have bottom surfaces that are located at a different level from the plug portions of the second wires 162 and vice versa.

According to example embodiments, for each of the first and second wires 161 and 162, the plug portion may have a reduced width (e.g., a reduced bottom width), compared with the line portion. For example, the first and second grooves 151 and 152 may be formed to have side surfaces at an angle with the top surface of the substrate 100, and this may lead to the difference in width between the line and plug portions. As the result of the reduction in width of the plug portion, it is possible to suppress the first and second wires 161 and 162 from being misaligned with respect to the first and second contact portions 131 and 132. For example, as illustrated in FIG. 7, a bottom width W1 of the line portion of the second line 162 may be greater than a bottom width W2 of the plug portion of the first line 161.

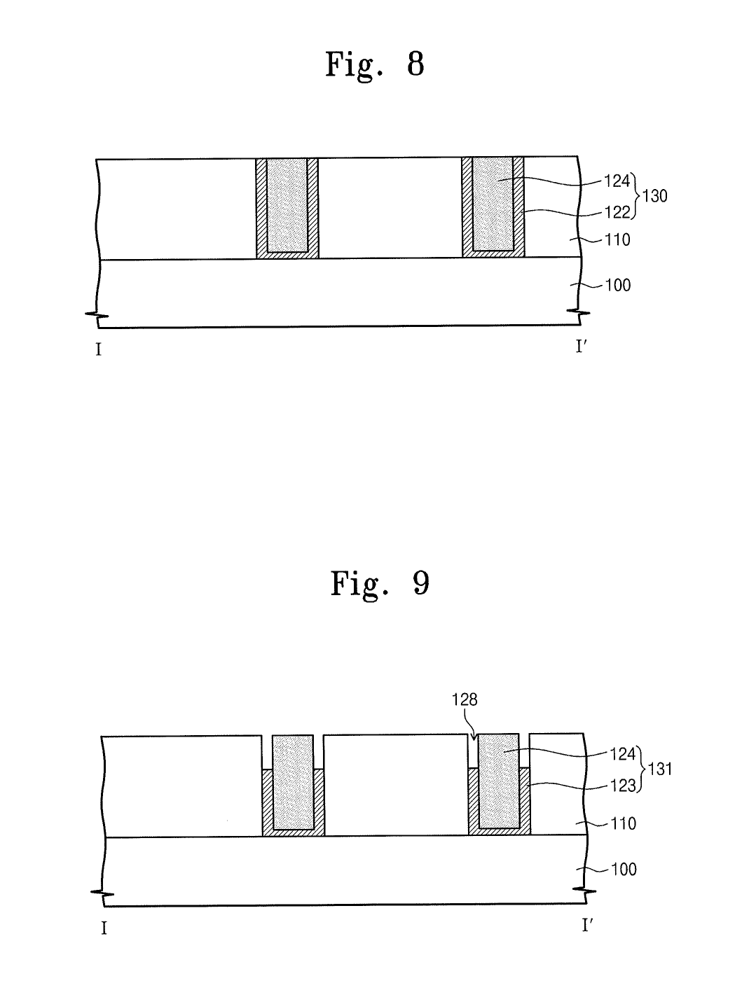

FIGS. 8 through 12 are sectional views illustrating stages in a method of fabricating an interconnection structure, according to other example embodiments. For the sake of brevity, a description of the elements and features of this example that are similar to those previously illustrated and described with reference to FIGS. 2 through 7 may not be repeated. In addition, the semiconductor device according to the present embodiment may have the same planar configuration as that described with reference to FIG. 1, and thus, the detailed description thereof will not be repeated.

Referring to FIGS. 1 and 8, the contact mold layer 110 may be formed on the substrate 100. The contact holes 120 may be formed on the substrate 100 to penetrate the contact mold layer 110. The contact holes 120 may penetrate the contact mold layer 110 and expose the substrate 100. The barrier layer 122 and the conductive layer 124 may be formed in each of the contact holes 120. The barrier layer 122 may be conformally formed to cover side and bottom surfaces of each of the contact holes 120. The conductive layer 124 may be formed to fill the contact holes 120 provided with (e.g., conformally covered with) the barrier layer 122. Thereafter, a polishing process may be performed to expose a top surface of the contact mold layer 110, and thus the contact portions 130 may be formed spaced apart from each other.

Referring to FIGS. 1 and 9, the barrier layers 122 may be selectively etched to form second recess regions 128. The formation of the second recess regions 128 may include partially etching a top surface of the barrier layer 122 provided in each of the contact holes 120. For example, the formation of the second recess regions 128 may include selectively etching the barrier layer 122 using an etch recipe that has etch selectivity with respect to the conductive layer 124. The etching process may include a dry and/or wet etching process.

As the result of the partial etching of the barrier layer 122, the barrier pattern 123 may be formed between the contact mold layer 110 and the conductive layer 124. The barrier pattern 123 may have a top surface lower than those of the conductive layer 124 and the contact mold layer 110 and higher than that of the substrate 100. In addition, as the result of the partial etching of the barrier layer 122, the second recess regions 128 may be formed on the barrier patterns 123 and between the conductive layers 124 and the contact mold layer 110. The barrier pattern 123 and the conductive layer 124 may constitute the first contact portion 131. In example embodiments, the second contact portions 132 may be formed to have the same technical features as those of the first contact portions 131.

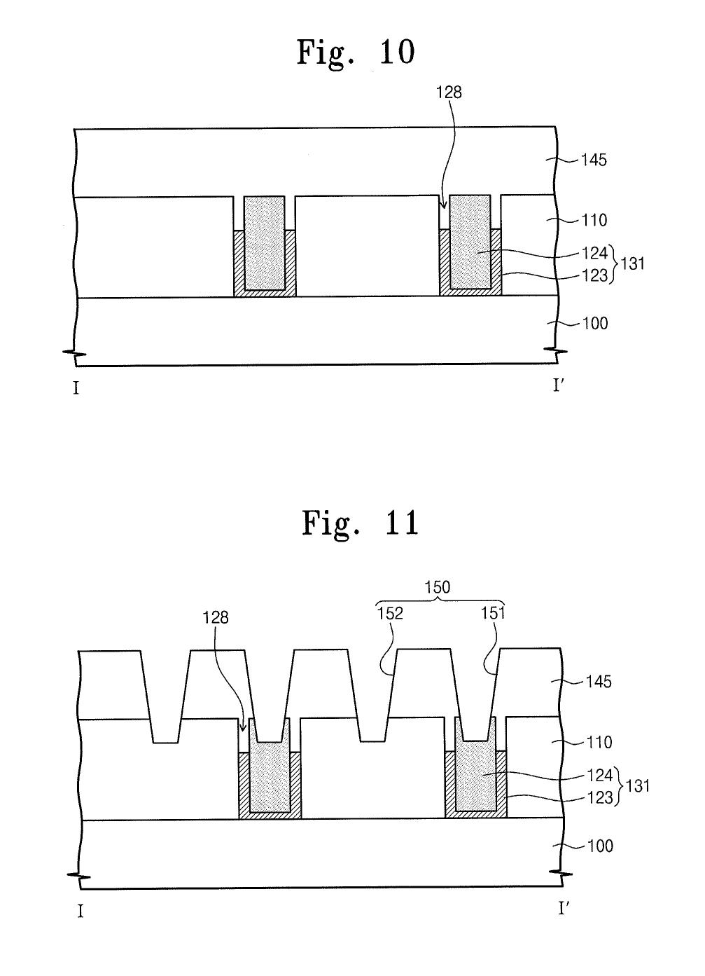

Referring to FIGS. 1 and 10, a wire mold layer 145 may be formed on the substrate 100. The wire mold layer 145 may be formed to cover the contact mold layer 110 and the contact portions 131 and 132. For example, the wire mold layer 145 may be formed to cover top surfaces of the contact mold layer 110 and the conductive layer 124 and to fill empty spaces (i.e., the second recess regions 128) between the conductive layer 124 and the contact mold layer 110. In example embodiments, the wire mold layer 145 may include a layer of oxide or nitride. The wire mold layer 145 may be formed of a material capable of filling the second recess regions 128.

Referring to FIGS. 1 and 11, the grooves 150 may be formed through the wire mold layer 145. The grooves 150 may include first grooves 151 and second grooves 152 exposing top surfaces of the contact portions 131 and 132, respectively. In example embodiments, the first and second grooves 151 and 152 may be formed to expose the top surface of the contact mold layer 110. Each of the second grooves 152 may be formed between the first grooves 151 spaced apart from each other. In other words, the first and second grooves 151 and 152 may be alternatingly arranged to each other, as illustrated in FIG. 11.

As illustrated in FIG. 11, the first and second grooves 151 and 152 on the contact mold layer 110 may be formed to have bottom surfaces lower than the top surface of the contact mold layer 110. The first and second grooves 151 and 152 on the contact portions 131 and 132 may be formed to have bottom surfaces lower than the top surface of the conductive layer 124. In example embodiments, the bottom surfaces of the first and second grooves 151 and 152 may be lower than the top surface of the conductive layer 124 and higher than the top surface of the barrier pattern 123. In other example embodiments, the first and second grooves 151 and 152 may be formed to have the bottom surfaces that are substantially coplanar with the top surfaces of the contact mold layer 110 and the conductive layer 124. However, the embodiments are not limited to these examples.

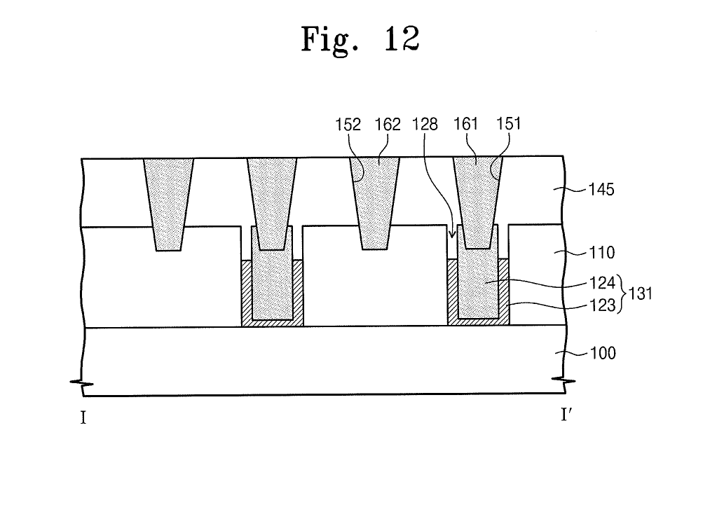

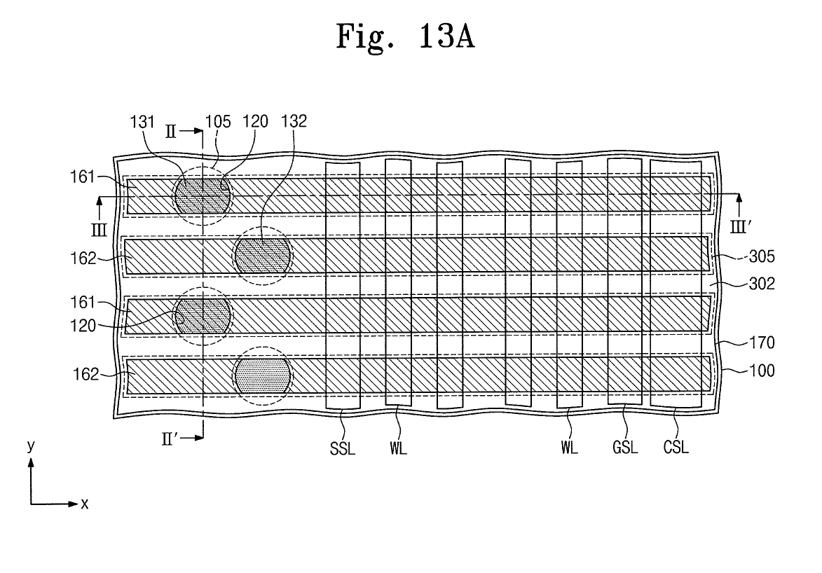

Referring to FIGS. 1 and 12, the first and second wires 161 and 162 may be formed on the substrate 100 to fill the first and second grooves 151 and 152, respectively. In a vertical sectional view taken along the second direction, the first wires 161 provided in the first grooves 151 may be electrically connected to the first contact portions 131, respectively. The second wires 162 provided in the second grooves 152 may be in contact with the contact mold layer 110. The first and second wires 161 and 162 may include at least one of metallic materials (e.g., of tungsten, aluminum, or copper). In example embodiments, the first and second wires 161 and 162 may be formed of the same material as the conductive layer 124, and in this case, the first and second wires 161 and 162 may be in contact with the conductive layer 124 without any interface therebetween. The formation of the first and second wires 161 and 162 may include forming a wire conductive layer (not illustrated) on the substrate 100, and then, performing a polishing process to expose the top surface of the wire mold layer 145.

In a vertical section view taken along the second direction, the first and second wires 161 and 162 may be arranged spaced apart from each other in an alternating manner. Here, each of the first contact portions 131 may include the conductive layer 124 and the barrier pattern 123 having a top surface lower than the conductive layer 124 and the wire mold layer 145 may fill the second recess regions 128. Accordingly, a space between the first and second wires 161 and 162 adjacent to each other may increase. In other words, for the semiconductor device according to example embodiments, space between the first and second wires 161 and 162 and space between the first and second wires 161 and 162 and the contact portions 131 and 132 may be increased, and thus the reduction in breakdown voltage of the semiconductor device may be substantially prevented.

FIGS. 13A, 13B, and 13C illustrate an example of a semiconductor memory device including the interconnection structure described with reference to FIGS. 1 through 7. FIG. 13A is a plan view illustrating a semiconductor device according to other example embodiments. FIG. 13B is a sectional view taken along line II-II′ of FIG. 13A, and FIG. 13C is a sectional view taken along line of FIG. 13A.

Referring to FIGS. 13A through 13C, a device isolation pattern 302 may be provided in the substrate 100 having a first conductivity type to define active portions 305. For example, the active portions 305 may be portions of the substrate 100 delimited by the device isolation pattern 302. Each of the active portions 305 may have a line shape elongated along the first direction and may be spaced apart from each other in the second direction crossing the first direction. For example, the first direction may be an x-direction of FIG. 13A, and the second direction may be a y-direction of FIG. 13A. The active portions 305 may be doped with dopants having the first conductivity type.

A string selection line SSL and a ground selection line GSL may be provided to cross the active portions 305. A plurality of word lines WL may be interposed between the string and ground selection lines SSL and GSL to cross the active portions 305. A drain region 310d and a source region 310s may be provided in two portions, respectively, of each of the active portion 305 adjacent to the string selection line SSL and the ground selection line GSL. The drain and source regions 310d and 310s may be formed in such a way that the string and ground selection lines SSL and GSL and the word lines WL are interposed therebetween.

In example embodiments, cell diffusion regions 310c may be provided in the active portions 305. The cell diffusion regions 310c may be formed at both sides of each of the word lines WL to serve as source/drain electrodes of cell transistors connected in series to each other. The drain region 310d and the source region 310s may be doped to have a second conductivity type. The cell diffusion regions 310c may be doped to have the second conductivity type. Alternatively, the cell diffusion regions 310c may have the same conductivity type as the substrate 100 or the active portions 305. In this case, a fringe field from the word line WL may induce inversion regions in the cell diffusion regions 310c, and the inversion regions may serve as the source/drain electrodes of the cell transistors.

Although not illustrated, each of the word lines WL may include, e.g., a tunnel insulating layer, a charge storing layer, a blocking insulating layer and a control gate, which are sequentially stacked on the active portion 305. In certain embodiments, the charge storing layer may be an isolated semiconductor pattern or a floating gate. In other embodiments, the charge storing layer may be an insulating layer with many charge-trap sites (e.g., a silicon nitride layer). The blocking insulating layer may include a high-k material (e.g., hafnium oxide or aluminum oxide) having a dielectric constant higher than the tunnel insulating layer. The blocking insulating layer may be provided in the form of a single- or multi-layered structure. The tunnel insulating layer may be provided in the form of a single- or multi-layered structure. The tunnel insulating layer may include an oxide layer, which may be formed using a thermal oxidation process. The string selection line SSL may include a string selection gate crossing the active portions 305 and a first gate insulating layer interposed between the string selection gate and the active portions 305. The ground selection line GSL may include a ground selection gate crossing the active portions 305 and a second gate insulating layer interposed between the ground selection gate and the active portions 305.

The word lines WL and the cell diffusion regions 310c may constitute the cell transistors. The string selection line SSL, the drain region 310d, and one of the cell diffusion regions 310c adjacent to the drain region 310d may constitute a string selection transistor, and the ground selection line GSL, the source region 310s and one of the cell diffusion regions 310c adjacent to the source region 310s may constitute a ground selection transistor.

Each of the active portions 305 may be used to constitute a cell string. The cell string may include the string and ground selection transistors and the cell transistors arranged in series therebetween to connect them. For example, the string selection transistor may be connected to one of the cell transistors adjacent to the drain region 310d, while the ground selection transistor may be connected to other of the cell transistors adjacent to the source region 310s. According to the present embodiment, the string and ground selection transistors and the cell transistors may be disposed at the substantially same level from the substrate 100. For example, the cell string may be a part of a cell array region in two-dimensional NAND FLASH memory device.

A lower interlayered dielectric 103 may be provided to cover the resulting structure provided with the gate lines SSL, WL and GSL. A common source line CSL may be provided in the lower interlayered dielectric 103 to extend parallel to the ground selection line GSL or the second direction. The common source line CSL may be connected to the source regions 310s.

Conductive pillars 105 may be connected to the drain regions 310d, respectively, through the lower interlayered dielectric 103. As illustrated in FIG. 13A, the conductive pillars 105 may have a zigzag arrangement. In example embodiments, the conductive pillars 105 may have top surfaces, which may be coplanar with that of the lower interlayered dielectric 103.

The contact mold layer 110, the first and second contact portions 131 and 132, the wire mold layer 140, and the first and second wires 161 and 162, described with reference to FIGS. 1 through 7, may be provided on the lower interlayered dielectric 103. An upper interlayered dielectric 170 may be provided on the first and second wires 161 and 162. The first and second contact portions 131 and 132 may be connected to top surfaces of the conductive pillars 105, respectively. The first wires 161 provided on the first contact portions 131 may be electrically connected to odd-numbered ones of the drain regions 310d arranged in the y-direction (e.g., drain regions 310d under the first wires 161). The second wires 162 provided on the second contact portions 132 may be electrically connected to even-numbered ones of the drain regions 310d arranged in the y-direction (e.g., drain regions 310d under the second wires 162). In example embodiments, the first and second wires 161 and 162 may serve as bit lines of the two-dimensional NAND FLASH memory device.

The first and second wires 161 and 162 may be disposed spaced apart from each and arranged in an alternating manner. According to example embodiments, in a vertical section view taken along line II-II′ of FIG. 13A, the first wires 161 may have bottom surfaces that are located at a different level from the bottom surfaces of the second wires 162, and thus, space between the first and second wires 161 and 162 and space between the first and second wires 161 and 162 and the contact portions 131 and 132 may be increased. Accordingly, it is possible to substantially prevent the reduction in breakdown voltage of the semiconductor device. In addition, the first and second wires 161 and 162 may be formed to have side surfaces at an angle to the top surface of the substrate 100. For example, each of the first and second wires 161 and 162 may have a downward tapered shape. This may allow for misalignment of the first and second wires 161 and 162 with respect to the first and second contact portions 131 and 132 to be suppressed.

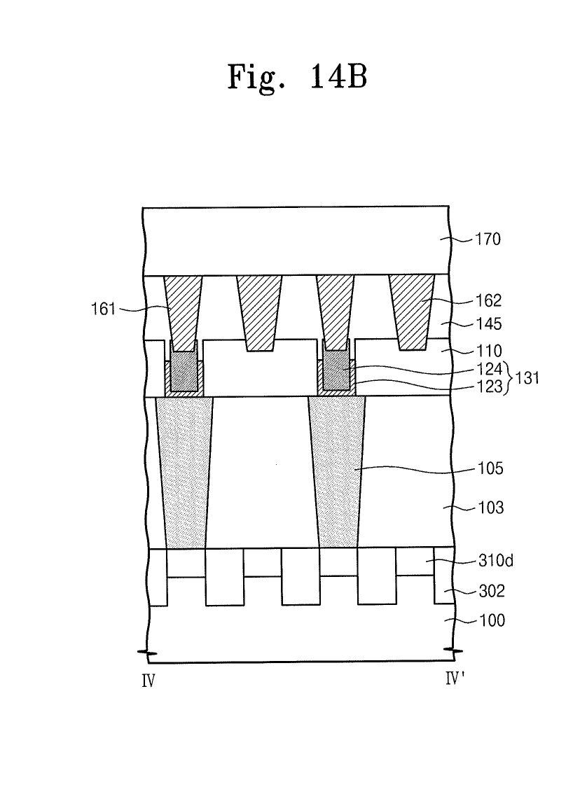

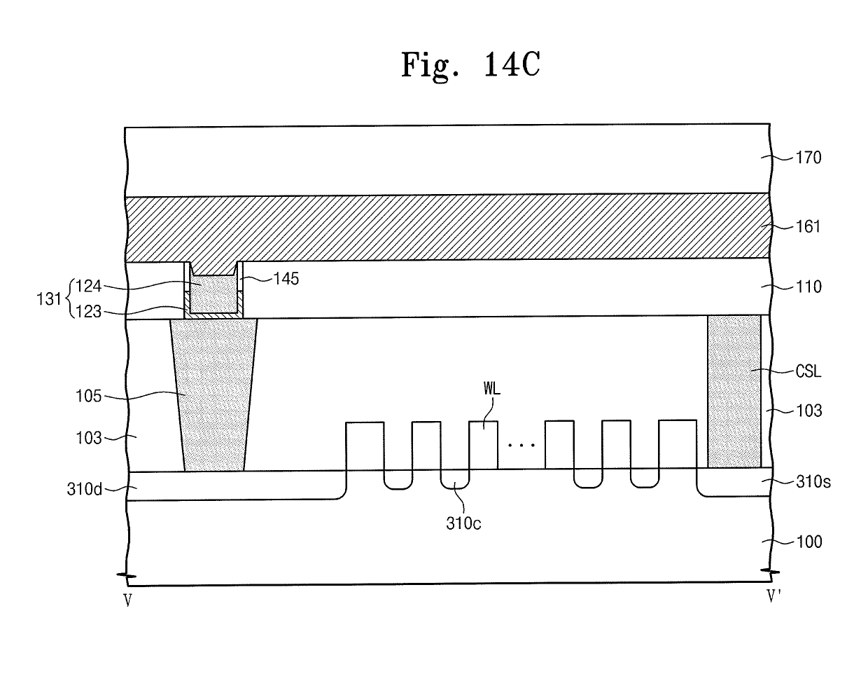

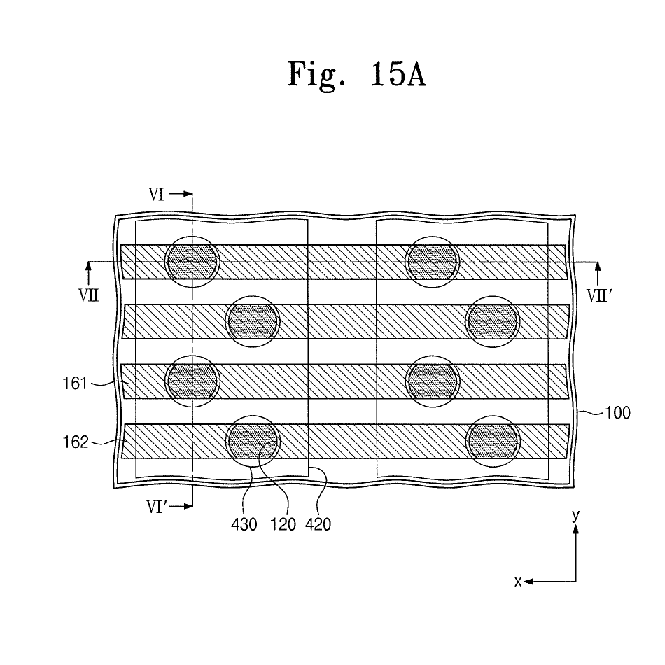

FIGS. 14A, 14B, and 14C illustrate an example of a semiconductor memory device including the interconnection structure described with reference to FIGS. 8 through 12. FIG. 14A is a plan view illustrating a semiconductor device according to other example embodiments. FIG. 14B is a sectional view taken along line IV-IV′ of FIG. 14A, and FIG. 14C is a sectional view taken along line V-V′ of FIG. 14A. For the sake of brevity, a description of the elements and features of this example that are similar to those previously illustrated and described with reference to FIGS. 13A through 13C will not be repeated.

Referring to FIGS. 14A through 14C, the first and second wires 161 and 162 and the first and second contact portions 131 and 132 may be configured to have substantially the same technical features as those described with reference to FIGS. 8 through 12. In other embodiments, the first contact portions 131 connected to the first wires 161 and the second contact portions 132 connected to the second wires 162 may be arranged in a column along the y-direction. In a vertical section view taken along the y-direction, the first and second wires 161 and 162 may be spaced apart from each other and be connected to the corresponding one of the first and second contact portions 131 and 132. Here, each of the first and second contact portions 131 and 132 may include the conductive layer 124 and the barrier pattern 123 having a top surface lower than the conductive layer 124, and the wire mold layer 145 may be formed to fill an empty space provided on the barrier pattern 123. Accordingly, it is possible to increase the space between the wires 161 and 162 that are adjacent to each other and increase the space between the wires 161 and 162 and the contact portions 131 and 132. This enables reduction in breakdown voltage of the semiconductor device to be substantially prevented.

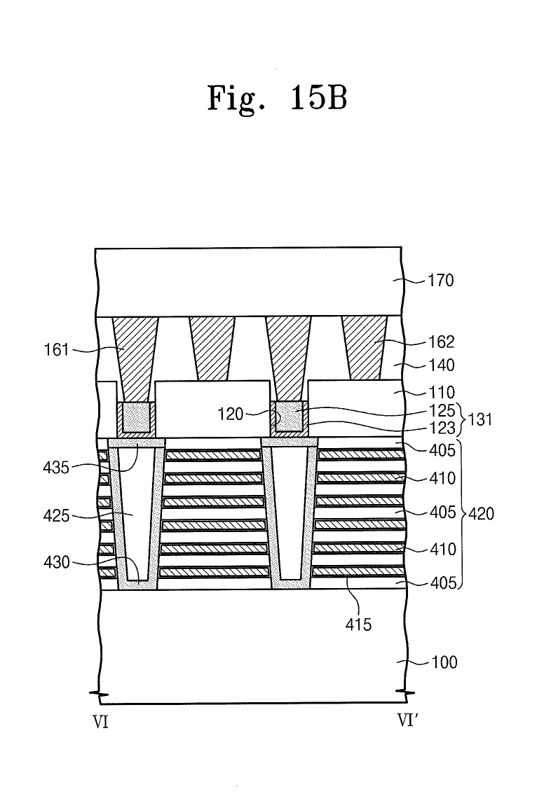

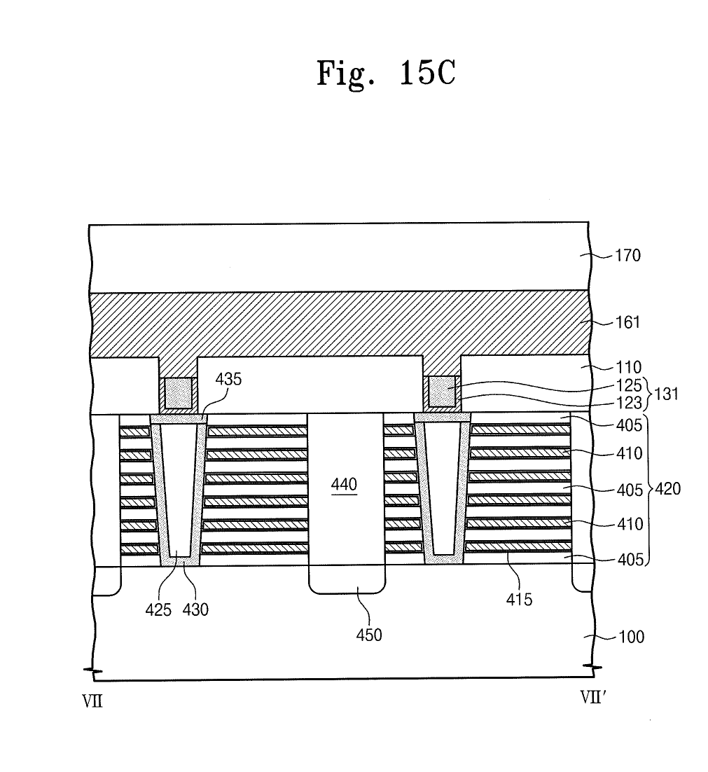

FIGS. 15A, 15B, and 15C illustrate an example of a vertical semiconductor memory device including the interconnection structure described with reference to FIGS. 1 through 7. FIG. 15A is a plan view illustrating a semiconductor device according to still other example embodiments. FIG. 15B is a sectional view taken along line VI-VI′ of FIG. 15A, and FIG. 15C is a sectional view taken along line VII-VII′ of FIG. 15A.

Referring to FIGS. 15A through 15C, a plurality of gate structures 420 may be provided on a substrate 100. The gate structures 420 may be spaced apart from each other in a first direction. The gate structures 420 may extend along a second direction crossing the first direction. For example, the first direction may be an x-direction of FIG. 15A, and the second direction may be a y-direction of FIG. 15A. The substrate 100 may be doped with dopants having the first conductivity type.

Each of the gate structures 420 may include dielectric patterns 405 and gate patterns 410, which are sequentially stacked on the substrate 100. A plurality of vertical active patterns 430 may be provided to penetrate each of the gate structures 420. For example, the vertical active patterns 430 may be connected to the substrate 100. In example embodiments, the vertical active patterns 430 may have a zigzag arrangement. Each of the vertical active patterns 430 may include a semiconductor material. For example, the vertical active pattern 430 may include an undoped semiconductor layer. Alternatively, the vertical active pattern 430 may be doped to have the first conductivity type.

A data storing layer 415 may be interposed between each of the vertical active patterns 430 and the gate patterns 410. The data storing layer 415 may include, e.g., a tunnel insulating layer, a charge storing layer, and a blocking insulating layer. The tunnel insulating layer may be disposed adjacent to the vertical active pattern 430, and the blocking insulating layer may be disposed adjacent to the gate patterns 410. The charge storing layer may be interposed between the tunnel insulating layer and blocking insulating layer.

In example embodiments, each of the vertical active patterns 430 may be provided in the form of a hollow shell and may be filled with a gap-filling insulating pattern 425. A capping semiconductor pattern 435 may be provided on the gap-filling insulating pattern 425. The capping semiconductor pattern 435 may be in contact with the vertical active pattern 430. The capping semiconductor pattern 435 may be doped to have the second conductivity type, thereby serving as a drain region. Alternatively, the vertical active pattern 430 may be provided in the form of a solid pillar. In this case, the semiconductor device may be configured without the gap-filling insulating pattern 425 and the capping semiconductor pattern 435.

In the case where the vertical active pattern 430 have the solid pillar shape, the uppermost portion of the vertical active pattern 430, located at a level higher than the uppermost one of the gate patterns 410, may be doped with dopants of the second conductivity type to form the drain region. A source region 450 may be provided in the substrate 100 between the gate structures 420. The source region 450 may be doped to have the second conductivity type. A device isolation pattern 440 may be provided to fill a gap between the gate structures 420.

The lowermost one of the gate patterns 410 may serve as a gate electrode of a ground selection transistor, while the uppermost one of the gate patterns 410 may serve as a gate electrode of a string selection transistor. The remaining ones of the gate patterns 410 may serve as gate electrodes of cell transistors, respectively. In example embodiments, the cell transistors may be formed at intersections between the remaining ones of the gate patterns 410 and the vertical active pattern 430. The cell transistor may be configured to exhibit a nonvolatile property. In example embodiments, the ground selection transistor, the cell transistors, and the string selection transistor may be electrically connected in series to form a cell string, and each of the vertical active patterns 430 may serve as a channel region for the cell string. In other words, the cell string may include a plurality of transistors vertically stacked on the substrate 100.

The contact mold layer 110, the first and second contact portions 131 and 132, the wire mold layer 140, and the first and second wires 161 and 162 may be provided on the gate structures 420 and the device isolation pattern 440 to have substantially the same technical features as those described with reference to FIGS. 1 through 7. The upper interlayered dielectric 170 may be provided on the first and second wires 161 and 162. The first and second wires 161 and 162 may be electrically connected to the drain regions of the vertical active patterns 430, respectively, via the contact portions 131 and 132.

In a vertical section view taken along the y-direction, portions of the first and second wires 161 and 162 on the first and second contact portions 131 and 132 may have bottom surfaces that are located at a vertical level different from other portions thereof at the outside of the first and second contact portions 131 and 132. Accordingly, it is possible to increase the space between the wires 161 and 162 adjacent to each other and to increase the space between the wires 161 and 162 and the contact portions 131 and 132. This enables reduction in breakdown voltage of the semiconductor device to be substantially prevented. In addition, the first and second wires 161 and 162 may be formed to have side surfaces at an angle to the top surface of the substrate 100. For example, each of the first and second wires 161 and 162 may have a downward tapered shape. This enables the misalignment of the first and second wires 161 and 162 with respect to the first and second contact portions 131 and 132 to be suppressed.

In example embodiments, the first and second wires 161 and 162, the first and second contact portions 131 and 132 may be configured to have substantially the same technical features as those described with reference to FIGS. 8 through 12.

The semiconductor devices disclosed above may be encapsulated using various and diverse packaging techniques. For example, the semiconductor devices according to the aforementioned embodiments may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a thin quad flat package (TQFP) technique, a small outline package (SOIC) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique and a wafer-level processed stack package (WSP) technique.

The package in which the semiconductor device according to one of the above embodiments is mounted may further include at least one semiconductor device (e.g., a controller and/or a logic device) that controls the semiconductor device.

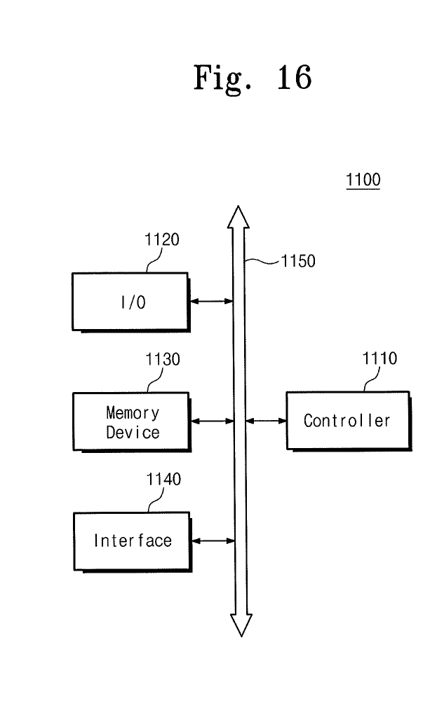

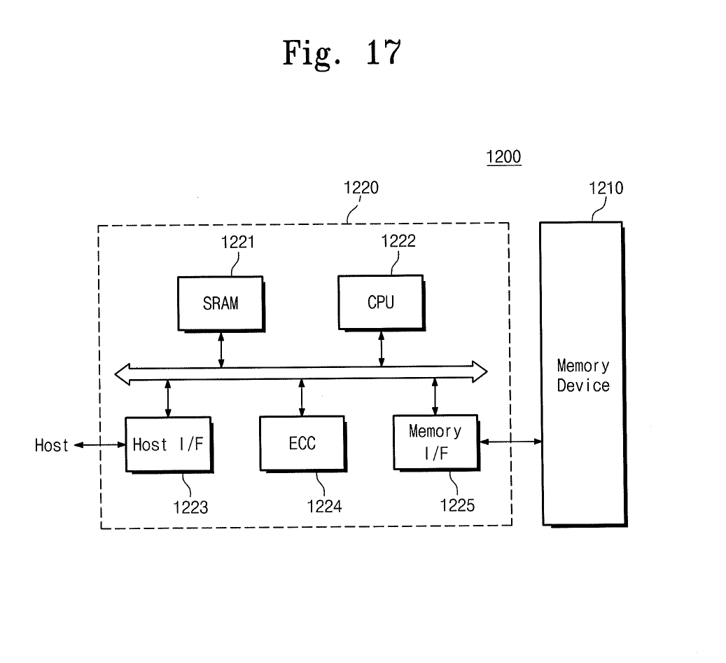

FIG. 16 is a schematic block diagram illustrating an example of electronic systems including a semiconductor device according to example embodiments.

Referring to FIG. 16, an electronic system 1100 according to example embodiments may include a controller 1110, an input/output (I/O) unit 1120, a memory device 1130, an interface unit 1140, and a bus 1150. At least two of the controller 1110, the I/O unit 1120, the memory device 1130, and the interface unit 1140 may communicate with each other through the bus 1150. The bus 1150 may correspond to a path through which electrical signals are transmitted.

The controller 1110 may include at least one of a microprocessor, a digital signal processor, a microcontroller or another logic device. The other logic device may have a similar function to any one of the microprocessor, the digital signal processor, and the microcontroller. In example embodiments, the controller 1110 may include a logic device based on one of the afore-described example embodiments. The I/O unit 1120 may include a keypad, a keyboard or a display unit. The memory device 1130 may store data and/or commands. The memory device 1130 may include at least one of the semiconductor memory devices according to the afore-described embodiments. The memory device 1130 may further include another type of semiconductor memory devices different from those described above. For example, the memory device 1130 may further include a nonvolatile memory device, a magnetic memory device, a phase change memory device, a dynamic random access memory (DRAM) device, and/or a static RAM (SRAM) device. The interface unit 1140 may transmit electrical data to a communication network or may receive electrical data from a communication network. The interface unit 1140 may operate wirelessly or by cable. For example, the interface unit 1140 may include an antenna for wireless communication or a transceiver for cable communication. Although not illustrated in the drawings, the electronic system 1100 may further include a fast DRAM or SRAM device that acts as a cache memory for improving an operation of the controller 1110.

The electronic system 1100 may be applied to, e.g., a personal digital assistant (PDA), a portable computer, a web tablet, a wireless phone, a mobile phone, a digital music player, a memory card or an electronic product. The electronic product may receive or transmit information data wirelessly.

FIG. 17 is a schematic block diagram illustrating an example of memory cards including a semiconductor device according to example embodiments.

Referring to FIG. 17, a memory card 1200 according to example embodiments may include a memory device 1210. The memory device 1210 may include at least one of the semiconductor memory devices according to the various above-described embodiments. In other embodiments, the memory device 1210 may further include another type of semiconductor memory devices different from those described above. For example, the memory device 1210 may further include a nonvolatile memory device, a dynamic random access memory (DRAM) device, and/or a static RAM (SRAM) device, which may be realized on the basis of the embodiments. The memory card 1200 may include a memory controller 1220 that controls data communication between a host and the memory device 1210.

The memory controller 1220 may include a central processing unit (CPU) 1222 that controls overall operations of the memory card 1200. In addition, the memory controller 1220 may include an SRAM device 1221 used as an operation memory of the CPU 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. Even though not illustrated in the drawings, the memory card 1200 may further include a read only memory (ROM) device that stores code data to interface with the host. The memory card 1200 may be used as a portable data storage card. Alternatively, the memory card 1200 may replace hard disks of computer systems as solid state disks (SSD) of the computer systems.

By way of summary and review, due to the increased demand for electronic devices with a fast speed and/or low power consumption, semiconductor devices may be expected to have a fast operating speed and/or a low operating voltage. Therefore it may be desirable to improve both the integration density and the reliability of the semiconductor device. However, increasing integration density of a semiconductor device may lead to a reduction in spaces between wires and between wires and contact portions, and consequently, the semiconductor device may suffer from deterioration in the reliability of the semiconductor device caused by a reduced breakdown voltage.

The example embodiments described above may allow for integration density to be increased while avoiding a reduction in breakdown voltage. According to example embodiments, in a vertical section view taken along a plane crossing the wires, a portion of one of the wires connected to the contact portion may have a bottom surface that is located at a different level (e.g., vertical level) from other portions of the wire disposed on the contact mold layer. This may increase the space between adjacent ones of the wires and between the wire and the contact portion. Thus, it is possible to substantially prevent the semiconductor device from having reduced breakdown voltage and from being deteriorated. In addition, a plug portion of the wire connected to the contact portion may have a bottom surface located below the top surface of the contact mold layer and the wire may have a downward tapered shape. This may enable misalignment of the wires with respect to the contact portions to be suppressed.

According to other example embodiments, each of the contact portions may include a barrier layer and a conductive layer, and the barrier layer may be selectively etched to have a top surface located below that of the conductive layer. For example, a recessed region may be formed on the barrier layer. The wire mold layer may be formed to fill the recessed region, and thus it is possible to increase the space between adjacent ones of the wires and between the wire and the contact portion. This may substantial prevent the semiconductor device from having reduced breakdown voltage and consequently being deteriorated.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor device, comprising:
a contact mold layer on a substrate, the contact mold layer defining first and second contact portions on the substrate;
a wire mold layer on the contact mold layer;
first wires penetrating the wire mold layer and extending in a first direction, the first wires contacting the first contact portions and the contact mold layer; and
second wires penetrating the wire mold layer and extending in the first direction, the second wires contacting the second contact portions and the contact mold layer, wherein:
the first and second wires are arranged in an alternating manner,
the first and second contact portions are arranged to have a zigzag configuration,
each of the first and second contact portions includes a conductive pattern and a barrier pattern that covers side and bottom surfaces of the conductive pattern, and
the barrier pattern of each of the first and second contact portions has a top surface lower than a top surface of the contact mold layer.

2. The device as claimed in claim 1, wherein:
a top surface of the conductive pattern of each of the first and second contact portions and the top surface of the contact mold layer are substantially coplanar with each other, and
the wire mold layer fills a gap between the conductive pattern of each of the first and second contact portions and the contact mold layer.

3. The device as claimed in claim 1, wherein the first and second wires have bottom surfaces that are lower than a top surface of the conductive pattern of each of the first and second contact portions and are higher than the top surface of the barrier pattern of each of the first and second contact portions.

4. The device as claimed in claim 1, wherein a top surface of the conductive pattern of each of the first and second contact portions is lower than the top surface of the contact mold layer and is substantially coplanar with the top surface of the barrier pattern of each of the first and second contact portions.

5. The device as claimed in claim 4, wherein:
each of the first and second wires includes a plug portion connected to a corresponding one of the first and second contact portions and a line portion spaced apart from the first and second contact portions, and
a bottom surface of the line portion of each of the first and second wires has a different vertical level than a bottom surface of the plug portion of each of the first and second wires.

6. The device as claimed in claim 1, wherein:
each of the first and second wires includes a plug portion connected to a corresponding one of the first and second contact portions and a line portion spaced apart from the first and second contact portions, and
the plug portion of each of the first and second wires has a bottom width that is smaller than a bottom width of the line portion of each of the first and second wires.

7-15. (canceled)

16. A semiconductor device, comprising:
a contact mold layer on a substrate, the contact mold layer defining first contact portions and second contact portions on the substrate, the first and second contact portions having a zigzag configuration; and
a wire mold layer on the contact mold layer, the wire mold layer defining first wires and second wires that extend substantially parallel to each other along a top surface of the contact mold layer, each of the first wires including a portion that extends below the top surface of the contact mold layer to contact one of the first contact portions, and each of the second wires including a portion that extends below the top surface of the contact mold layer to contact one of the second contact portions.

17. The device as claimed in claim 16, wherein:
the portion of each of the first wires that extends below the top surface of the contact mold layer has a bottom width that is smaller than a bottom width of a portion of each of the first wires that extends along the top surface of the contact mold layer, and
the portion of each of the second wires that extends below the top surface of the contact mold layer has a bottom width that is smaller than a bottom width of a portion of each of the second wires that extends along the top surface of the contact mold layer.

18. The device as claimed in claim 16, wherein:
the first and second contact portions each include a conductive pattern and a barrier pattern that covers side and bottom surfaces of the conductive pattern, and
the conductive pattern and the barrier pattern of each of the first and second contact portions have top surfaces that are substantially coplanar with each other and are below the top surface of the contact mold layer.

19. The device as claimed in claim 16, wherein:
the first and second contact portions each include a conductive pattern and a barrier pattern that covers side and bottom surfaces of the conductive pattern,
the conductive pattern of each of the first and second contact portions has a top surface that is substantially coplanar with the top surface of the contact mold layer, and
the barrier pattern of each of the first and second contact portions has a top surface that is below the top surface of the contact mold layer.

20. The device as claimed in claim 16, wherein:
the first and second contact portions each include a conductive pattern and a barrier pattern that covers side and bottom surfaces of the conductive pattern,
the barrier pattern of each of the first and second contact portions has a top surface that is below the top surface of the contact mold layer, and
a portion of the wire mold layer extends below the top surface of the contact mold layer and is above the top surface of the barrier pattern of each of the first and second contact portions.
